(19) United States
(12) Patent Application Publication
(10) Pub. No.: US 2012/0285535 A1
(43) Pub. Date: Nov. 15, 2012

(54) SOLAR CELL MODULE

(75) Inventors: Yusaku TAGO, Otsu-shi (JP); Yasuo KADONAGA, Kishiwada-shi (JP)

(73) Assignee: SANYO ELECTRIC CO., LTD., Moriguchi-shi (JP)

(21) Appl. No.: 13/556,258

(22) Filed: Jul. 24, 2012

Related U.S. Application Data
(63) Continuation of application No. PCT/JP2011/050748, filed on Jan. 18, 2011.

(30) Foreign Application Priority Data
Jan. 28, 2010 (JP) 2010-016445

(51) Int. Cl. H01L 31/0203

(52) U.S. Cl. 136/259

(57) ABSTRACT

There is provided a solar cell module capable of discharging water retained on the upper surface of a solar cell panel therefrom while maintaining the mechanical strength of a frame body. This solar cell module includes a gasket including a groove to discharge the water retained on the upper surface of the solar cell panel, arranged between the solar cell panel and the frame body.

### CROSS-REFERENCE TO RELATED APPLICATIONS

The priority application number JP2010-016445, Solar Cell Module, Jan. 28, 2010, Yusaku Tago and Yasuo Kadonaga, upon which this patent application is based is hereby incorporated by reference. This application is a continuation of PCT/JP2011/050748, Solar Cell Module, Jan. 18, 2011, Yusaku Tago and Yasuo Kadonaga.

### BACKGROUND OF THE INVENTION

1. Field of the Invention

The present invention relates to a solar cell module, and more particularly, it relates to a solar cell module including a gasket.

2. Description of the Background Art

A solar cell module including a gasket is known in general, as disclosed in Japanese Patent Laying-Open No. 2000-243998, for example.

The aforementioned Japanese Patent Laying-Open No. 2000-243998 discloses a solar cell module including a solar cell panel, an outer frame fixing the solar cell panel by holding end portions of the solar cell panel by an upper portion, a lower portion, and side surface portions thereof, and a sealant (gasket) made of silicon resin arranged between the solar cell panel and the outer frame.

However, in the solar cell module described in the aforementioned Japanese Patent Laying-Open No. 2000-243998, water retained on the upper surface of the solar cell panel is held back by the upper portion of the outer frame located on the upper surface side of the solar cell panel, whereby it is difficult to discharge the water.

In this regard, there is proposed a technique to solve the aforementioned problem in Japanese Utility Model Laying-Open No. 6-017257 (1994), for example. The aforementioned Japanese Utility Model Laying-Open No. 6-017257 discloses a solar cell module including a solar cell panel, a frame (frame body) fixing the solar cell panel by holding the solar cell panel by an upper portion, a lower portion, and side surface portions thereof, and a butyl rubber (gasket) arranged between the solar cell panel and the frame, in which a notch to discharge water is formed in a side of the frame located on the lower side when the solar cell module is obliquely placed. The notch is formed by partially notching the upper portion of the frame, and in this notch, the upper surface of the solar cell panel, the butyl rubber, and the frame (upper surfaces of the side surface portions) are coplanar with each other. Consequently, water retained on the upper surface of the solar cell panel is discharged through the notch.

However, in the solar cell module disclosed in the aforementioned Japanese Utility Model Laying-Open No. 6-017257, the upper portion of the frame is notched in the side of the frame located on the lower side when the solar cell module is obliquely placed, and hence the mechanical strength of the side of the frame (frame body) located on the lower side when the solar cell module is obliquely placed may become insufficient.

### SUMMARY OF THE INVENTION

The present invention has been proposed in order to solve the aforementioned problems, and an object of the present invention is to provide a solar cell module capable of discharging water retained on the upper surface of a solar cell panel while maintaining the mechanical strength of a frame body.

In order to attain the aforementioned object, a solar cell module according to an aspect of the present invention includes a solar cell panel including a solar cell, a frame body to support an end portion of the solar cell panel, and a gasket including a groove to discharge water retained on the upper surface of the solar cell panel, arranged between the solar cell panel and the frame body.

In the solar cell module according to the aspect of the present invention, as hereinabove described, the groove to discharge the water retained on the upper surface of the solar cell panel is formed in the gasket, whereby the water retained on the upper surface of the solar cell panel can be discharged through the groove. Furthermore, it is not necessary to form a flow channel by notching an upper portion of the frame body in order to discharge the water retained on the upper surface of the solar cell panel, and hence the mechanical strength of the frame body can be maintained. Therefore, the water retained on the upper surface of the solar cell panel can be discharged while the mechanical strength of the frame body is maintained.

In the aforementioned solar cell module according to the aspect, the solar cell panel preferably has a substantially rectangular shape in plan view, and the groove of the gasket preferably extends from an end portion of the gasket closer to the upper surface of the solar cell panel to intersect with the extensional direction of a side surface of the solar cell panel on which the gasket is arranged. According to this structure, the groove can extend from the end portion of the gasket closer to the upper surface of the solar cell panel to the outside along a separating direction, dissimilarly to a case where the groove of the gasket extends parallel to the extensional direction of the side surface of the solar cell panel, and hence the water retained on the upper surface of the solar cell panel can be discharged through the groove.

In this case, the groove of the gasket preferably extends from the end portion of the gasket closer to the upper surface of the solar cell panel to be substantially orthogonal to the extensional direction of the side surface of the solar cell panel on which the gasket is arranged. According to this structure, the overall length of the groove in which water flows can be reduced as compared with a case where the groove obliquely intersect with the extensional direction of the side surface of the solar cell panel, and hence the water retained on the upper surface of the solar cell panel can be more reliably discharged through the groove.

In the aforementioned solar cell module according to the aspect, the groove of the gasket is preferably formed in a surface coming into contact with the solar cell panel. According to this structure, the water retained on the upper surface of the solar cell panel can be reliably discharged as compared with a case where the groove is formed in a portion (region) different from the surface coming into contact with the solar cell panel.

In the aforementioned solar cell module according to the aspect, the groove of the gasket is preferably formed in an end portion of the gasket closer to the upper surface of the solar cell panel and at least a region of the gasket corresponding to the upper surface of the solar cell panel. According to this structure, the water retained on the upper surface of the solar cell panel can be discharged to at least the vicinity of the side surface of the solar cell panel through the groove.

In the aforementioned solar cell module according to the aspect, the solar cell panel preferably has a substantially rectangular shape in plan view, and the groove of the gasket is preferably formed at least in the vicinity of the four corners of the solar cell panel. According to this structure, when one of the four corners of the solar cell panel is arranged below the other corners, the water retained on the upper surface of the corner of the solar cell panel arranged on the lower side can be discharged through the groove formed in the vicinity of the corner of the gasket corresponding to the corner of the solar cell panel.

In the aforementioned solar cell module according to the aspect, the solar cell panel preferably has a substantially rectangular shape in plan view, and the groove of the gasket is preferably formed in a region corresponding to at least a partial region of each of the four sides of the solar cell panel. According to this structure, when one of the four sides of the solar cell panel is arranged below the other sides, the water retained on the upper surface of the side of the solar cell panel arranged on the lower side can be discharged through the groove formed in the region corresponding to at least the partial region of the side of the solar cell panel.

In this case, a plurality of grooves of the gasket are preferably formed in a region corresponding to a substantially entire region of the four sides of the solar cell panel. According to this structure, when one of the four sides of the solar cell panel is arranged below the other sides, the water retained on the upper surface of the side of the solar cell panel arranged on the lower side can be reliably discharged through the plurality of grooves formed in a substantially entire region of the side of the gasket corresponding to the side of the solar cell panel arranged on the lower side.

In the aforementioned solar cell module according to the aspect, the gasket preferably further includes a flat portion formed between a plurality of grooves, coming into surface contact with the solar cell panel. According to this structure, flow channels each having a closed periphery can be configured by a surface of the solar cell panel and the grooves of the gasket supporting the solar cell panel in a state where the flat portion is in close contact with the solar cell panel. Thus, water can be inhibited from leaking from portions other than the grooves during discharge.

In the aforementioned solar cell module according to the aspect, the groove of the gasket preferably extends from an end portion of the gasket closer to the upper surface of the solar cell panel to an end portion of the gasket closer to the lower surface of the solar cell panel. According to this structure, the water retained on the upper surface of the solar cell panel can be discharged through the groove of the gasket extending from the end portion of the gasket closer to the upper surface of the solar cell panel to the end portion of the gasket closer to the lower surface of the solar cell panel.

In the aforementioned solar cell module according to the aspect, a hole is preferably formed as a discharge portion in a region of the gasket corresponding to a side surface of the solar cell panel. According to this structure, the water retained on the upper surface of the solar cell panel can be discharged through not only the groove of the gasket but also the hole formed as a discharge portion.

In this case, the groove of the gasket is preferably formed to be connected to the hole. According to this structure, the water retained on the upper surface of the solar cell panel can be easily discharged through the groove of the gasket and the hole connected to the groove.

In the aforementioned solar cell module in which the groove of the gasket is connected to the hole, the solar cell panel preferably further includes an upper surface cover portion made of a water-resistant material, arranged on the upper surface of the solar cell panel and a lower surface cover portion arranged on the lower surface of the solar cell panel, the groove of the gasket is preferably formed in a surface coming into contact with the solar cell panel, and extends from an end portion of the gasket closer to the upper surface of the solar cell panel to the hole, and the hole of the gasket is preferably formed in a region corresponding to a vicinity of a boundary between the upper surface cover portion and the lower surface cover portion of the side surface of the solar cell panel or a region corresponding to a position closer to the upper surface of the solar cell panel beyond the vicinity of the boundary. According to this structure, the water retained on the upper surface of the solar cell panel is allowed to flow employing a portion between the water-resistant upper surface cover portion and the groove of the gasket as a flow channel, and the water can be discharged through the hole formed in the region corresponding to the vicinity of the boundary between the upper surface cover portion and the lower surface cover portion of the side surface of the solar cell panel or the region corresponding to the position closer to the upper surface of the solar cell panel beyond the vicinity of the boundary. Thus, the water can be inhibited from flowing employing a portion between the lower surface cover portion having relatively low water resistance as compared with the upper surface cover portion and the gasket as a flow channel.

In the aforementioned solar cell module in which the groove of the gasket is connected to the hole, a plurality of adjacent grooves of the gasket are preferably formed to be connected to the common hole. According to this structure, even if the plurality of grooves are close to each other and it is difficult to provide a hole with respect to each of the plurality of grooves, the common hole is formed with respect to the plurality of grooves so that the hole serving as a discharge portion can be reliably formed in the gasket.

In the aforementioned solar cell module in which the hole is formed in the gasket, the frame body preferably includes an upper portion located in a region corresponding to the upper surface of the solar cell panel, a lower portion located in a region corresponding to the lower surface of the solar cell panel, and a side surface portion located in a region corresponding to the side surface of the solar cell panel, a discharge hole to discharge water is preferably provided in the side surface portion of the frame body, and the water retained on the upper surface of the solar cell panel is preferably discharged through the groove and the hole of the gasket and the discharge hole of the side surface portion of the frame body. According to this structure, the water discharged to the side of the gasket closer to the frame body through the groove of the gasket and the hole provided in a region of the gasket corresponding to the side surface of the solar cell panel can be discharged to an external portion of the frame body through the discharge hole provided in the side surface portion of the frame body. Furthermore, the discharge hole to discharge the water to the external portion is provided in the side surface portion of the frame body, whereby the mechanical strength of the frame body can be further maintained as compared with a case where the upper portion of the frame body is notched.

In the aforementioned solar cell module in which the discharge hole is provided in the side surface portion of the frame body, the hole of the gasket is preferably formed to be connected to the discharge hole of the frame body. According to this structure, the water discharged to the hole through the groove can be reliably discharged to the external portion through the hole and the discharge hole connected to the hole.

In the aforementioned solar cell module according to the aspect, a notch is preferably provided as a discharge portion in a region of the gasket corresponding to the lower surface of the solar cell panel. According to this structure, the water retained on the upper surface of the solar cell panel can be discharged through not only the groove of the gasket but also the notch formed as a discharge portion.

In this case, the groove of the gasket is preferably formed to be connected to the notch. According to this structure, the water retained on the upper surface of the solar cell panel can be easily discharged through the groove of the gasket and the notch connected to the groove.

In the aforementioned solar cell module in which the groove of the gasket is connected to the notch, a plurality of adjacent grooves of the gasket are preferably formed to be connected to the common notch. According to this structure, even if the plurality of grooves are close to each other and it is difficult to provide a notch with respect to each of the plurality of grooves, the common notch is formed with respect to the plurality of grooves so that the notch serving as a discharge portion can be reliably formed in the gasket.

In the aforementioned solar cell module in which the notch is provided in the gasket, the frame body preferably includes an upper portion located in a region corresponding to the upper surface of the solar cell panel, a lower portion located in a region corresponding to the lower surface of the solar cell panel, and a side surface portion located in a region corresponding to a side surface of the solar cell panel, a discharge hole to discharge water is preferably provided in the side surface portion or the lower portion of the frame body, and the water retained on the upper surface of the solar cell panel is preferably discharged through the groove and the notch of the gasket and the discharge hole of the frame body. According to this structure, the water discharged to the side of the gasket closer to the frame body through the groove of the gasket and the notch provided in a region of the gasket corresponding to the lower surface of the solar cell panel can be discharged to the external portion of the frame body through the discharge hole provided in the side surface portion or the lower portion of the frame body. Furthermore, the discharge hole to discharge the water to the external portion is provided in the side surface portion or the lower portion of the frame body, whereby the mechanical strength of the frame body can be further maintained as compared with a case where the upper portion of the frame body is notched.

### BRIEF DESCRIPTION OF THE DRAWINGS

FIG. 1 is a perspective view of a solar cell module according to a first embodiment of the present invention;

FIG. 2 is a plan view of the solar cell module according to the first embodiment of the present invention;

FIG. 3 is a sectional view corresponding to a flat portion of a gasket of the solar cell module taken along the line 1000-1000 in FIG. 2;

FIG. 4 is a plan view of the gasket according to the first embodiment of the present invention;

FIG. 5 is a perspective view of a part of the gasket according to the first embodiment of the present invention;

FIG. 6 is a side elevational view of the gasket as viewed in a direction A in FIG. 4;

FIG. 7 is a developed view of the gasket according to the first embodiment of the present invention;

FIG. 8 is a sectional view of the gasket taken along the line 3000-3000 in FIG. 7;

FIG. 9 is a sectional view corresponding to a groove of the gasket of the solar cell module taken along the line 2000-2000 in FIG. 2;

FIG. 10 is a perspective view of a solar cell module according to a second embodiment of the present invention;

FIG. 11 is a sectional view of a gasket and a frame body of the solar cell module taken along the line 4000-4000 in FIG. 10;

FIG. 12 is a perspective view of a part of the gasket according to the second embodiment of the present invention;

FIG. 13 is a side elevational view of the gasket as viewed in a direction B in FIG. 11;

FIG. 14 is a developed view of the gasket according to the second embodiment of the present invention;

FIG. 15 is a sectional view of the gasket taken along the line 7000-7000 in FIG. 14;

FIG. 16 is a sectional view corresponding to a groove and a hole of the gasket of the solar cell module taken along the line 6000-6000 in FIG. 11;

FIG. 17 is a perspective view of a part of a gasket according to a modification of the second embodiment of the present invention;

FIG. 18 is a side elevational view of the gasket according to the modification of the second embodiment of the present invention;

FIG. 19 is a sectional view corresponding to a contact portion of the gasket taken along the line 8000-8000 in FIG. 18;

FIG. 20 is a sectional view corresponding to a groove and a hole of the gasket taken along the line 9000-9000 in FIG. 18;

FIG. 21 is a perspective view of a part of a gasket according to a third embodiment of the present invention;

FIG. 22 is a side elevational view of the gasket according to the third embodiment of the present invention;

FIG. 23 is a developed view of the gasket according to the third embodiment of the present invention;

FIG. 24 is a sectional view corresponding to a groove and a notch of the gasket taken along the line 11000-11000 in FIG. 22;

FIG. 25 is a sectional view corresponding to a groove and a notch of a gasket of a solar cell module according to a modification of the third embodiment of the present invention;

FIG. 26 is a perspective view of a part of a gasket according to a first modification of each of the first to third embodiments of the present invention;

FIG. 27 is a developed view of the gasket according to the first modification of each of the first to third embodiments of the present invention;

FIG. 28 is a perspective view of a part of a gasket according to a second modification of each of the first to third embodiments of the present invention; and

FIG. 29 is a side elevational view of the gasket according to the second modification of each of the first to third embodiments of the present invention.

### DESCRIPTION OF THE PREFERRED EMBODIMENTS

Embodiments of the present invention are now described with reference to the drawings.

### First Embodiment

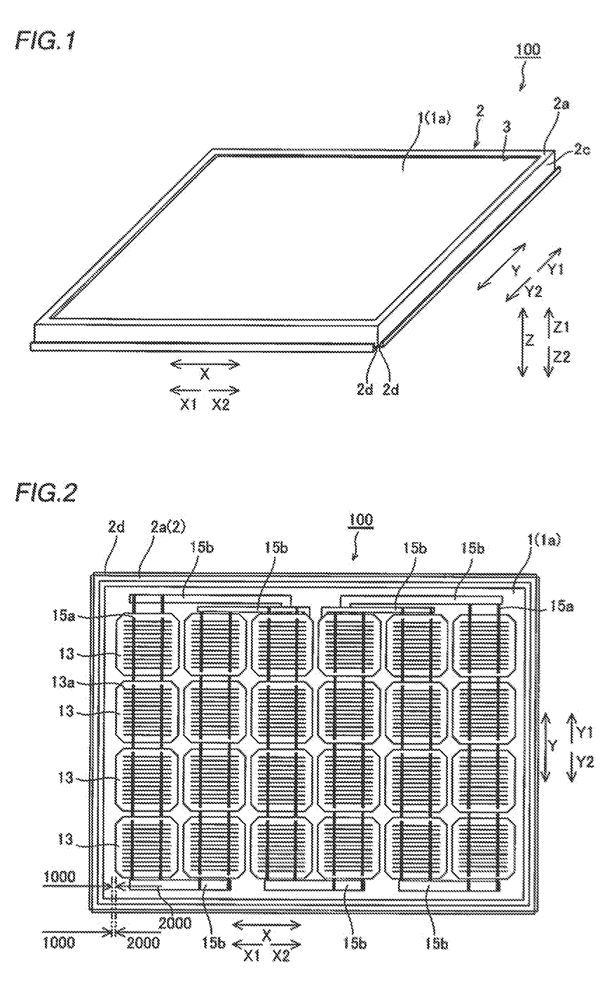

As shown in FIGS. 1 and 2, a solar cell module 100 according to a first embodiment is constituted by a solar cell panel 1, a frame body 2 made of metal such as aluminum to support the solar cell panel 1, and a gasket 3 (see FIG. 1) made of rubber or the like arranged between the solar cell panel 1 and the frame body 2. In plan view, the solar cell panel 1 has a substantially rectangular shape.

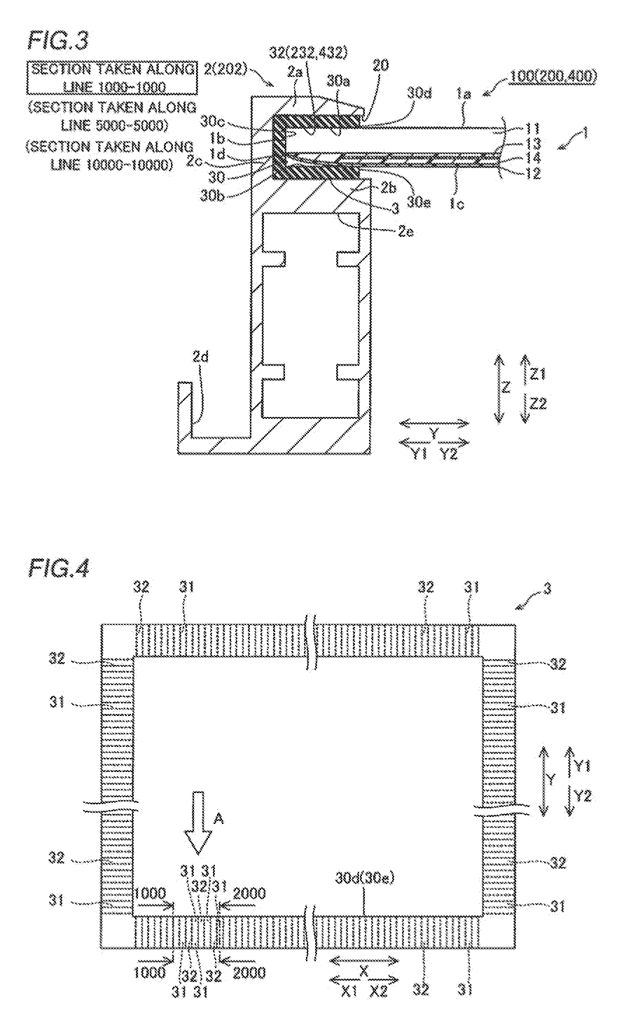

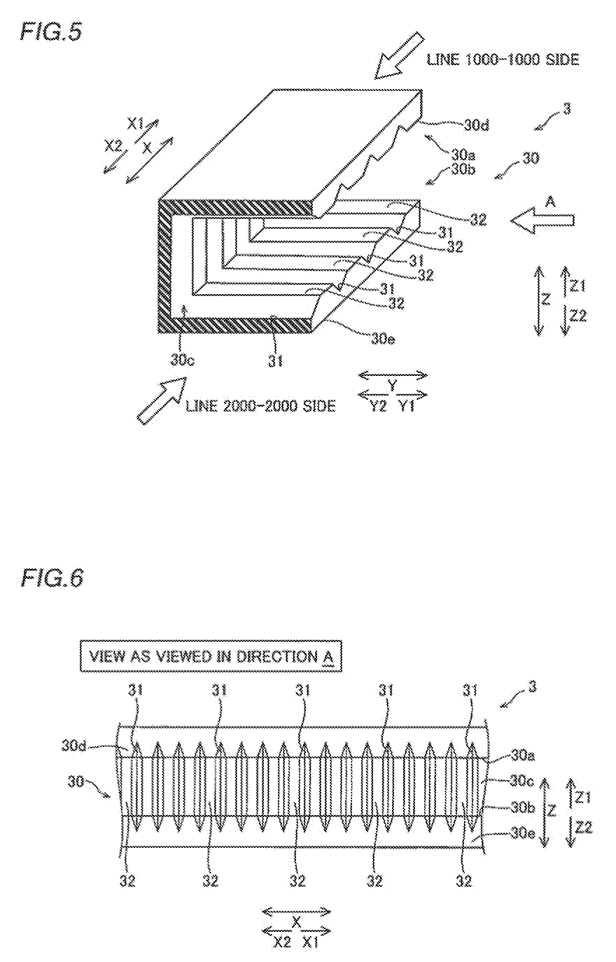

As shown in FIG. 3, the solar cell panel 1 is constituted by a water-resistant upper surface-side cover 11 made of glass, a weather-resistant lower surface-side cover 12 made of a resin film of polyethylene terephthalate (PET) or the like, a plurality of solar cells 13 arranged between the upper surface-side cover 11 and the lower surface-side cover 12, and a filler 14 provided between the upper surface-side cover 11 (lower surface-side cover 12) and the plurality of solar cells 13. The upper surface-side cover 11 is an example of the “upper surface cover portion” in the present invention, and the lower surface-side cover 12 is an example of the “lower surface cover portion” in the present invention.

The upper surface 1a and the upper side surfaces 1b of the solar cell panel 1 on which the upper surface-side cover 11 is located are substantially flat. The lower surface 1c of the solar cell panel 1 on which the lower surface-side cover 12 is located is substantially flat, while the lower side surfaces 1d of the solar cell panel 1 on which the lower surface-side cover 12 is located are substantially arcuate. The upper side surfaces 1b are examples of the “side surface of the solar cell panel” in the present invention.

As shown in FIG. 2, each of the plurality of solar cells 13 is formed with a finger electrode 13a extending along a direction X. The plurality of solar cells 13 are connected in series with each other by wiring members 15a, and the plurality of solar cells 13 connected in series with each other are connected in series with each other by connecting members 15b.

As shown in FIGS. 1 and 2, the frame body 2 is provided in the form of a substantially rectangular frame to surround the upper surface 1a and the lower surface 1c in the vicinity of end portions of the solar cell panel 1, the upper side surfaces 1b, and the lower side surfaces 1d in plan view. The frame body 2 includes an upper portion 2a opposed to the upper surface 1a of the solar cell panel 1, a lower portion 2b opposed to the lower surface 1c of the solar cell panel 1, and a side surface portion 2c opposed to the upper side surfaces 1b and the lower side surfaces 1d of the solar cell panel 1, and these upper portion 2a, lower portion 2b, and side surface portion 2c form a recess portion 20 in which the solar cell panel 1 and the gasket 3 are arranged, as shown in FIG. 3. Outer peripheral grooves 2d and hollow portions 2e allowing water to be discharged are provided in both end portions of the frame body 2 in the direction X and both end portions of the frame body 2 in a direction Y (see FIG. 1). These hollow portions 2e are connected with the outer peripheral grooves 2d through unshown holes.

As shown in FIG. 4, the gasket 3 is provided in the form of a substantially rectangular frame in plan view. The gasket 3 has a substantially U-shaped section, as shown in FIG. 5. The inner surface 30 of the gasket 3 includes an upper inner surface 30a supporting the upper surface 1a in the vicinity of the end portions of the solar cell panel 1, a lower inner surface 30b supporting the lower surface 1c in the vicinity of the end portions of the solar cell panel 1, and a side inner surface 30c supporting the upper side surfaces 1b and the lower side surfaces 1d of the solar cell panel 1. The inner surface 30 is an example of the “surface coming into contact with the solar cell panel” in the present invention.

According to the first embodiment, a plurality of grooves 31 to discharge water are formed in a substantially entire region of the inner surface 30 of the gasket 3, that is the surface coming into contact with the solar cell panel 1, on the four sides at constant intervals, as shown in FIG. 4. These grooves 31 are formed also in the vicinity of the corners of the gasket 3 corresponding to the four corners (see FIG. 2) of the solar cell panel 1. As shown in FIG. 8, the grooves 31 each have a substantially triangular section. Substantially flat portions 32 are formed between the respective adjacent grooves 31.

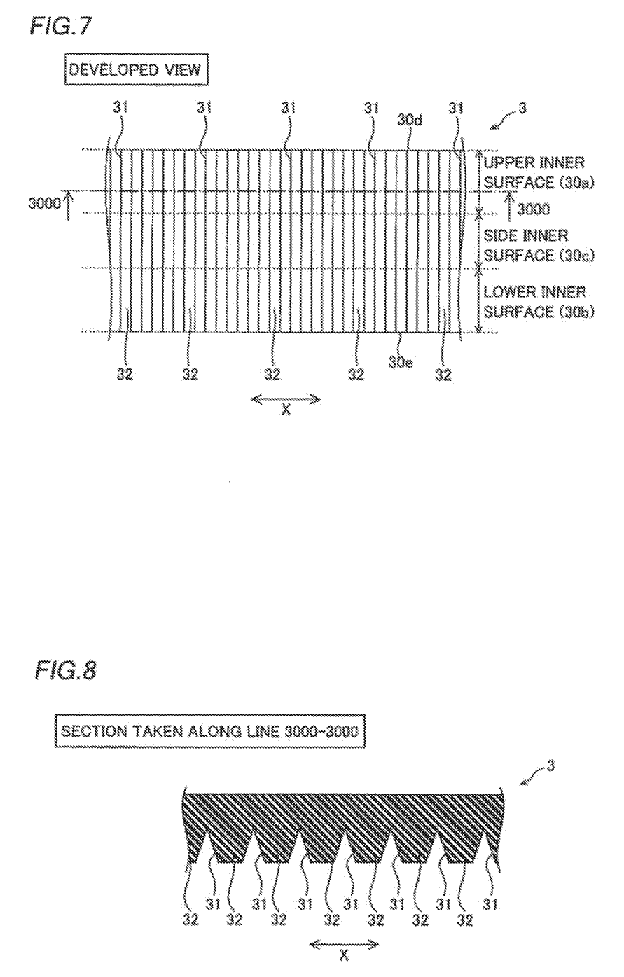

According to the first embodiment, the grooves 31 are formed to extend from a first end portion 30d of the upper inner surface 30a of the inner surface 30 to a second end portion 30e of the lower inner surface 30b through the upper inner surface 30a, the side inner surface 30c, and the lower inner surface 30b, as shown in FIGS. 5 and 7. As shown in FIG. 4, in a portion of the gasket 3 along arrow Y1 (Y2), the grooves 31 formed in the upper inner surface 30a and the lower inner surface 30b are formed to extend in the direction Y substantially orthogonal to the direction X that is the extensional direction of the corresponding upper side surface 1b and lower side surface 1d of the solar cell panel 1. The grooves 31 formed in the side inner surface 30c are formed to extend in a direction Z substantially orthogonal to the direction X. The first end portion 30d is an example of the “end portion of the gasket closer to the upper surface of the solar cell panel” in the present invention, and the second end portion 30e is an example of the “end portion of the gasket closer to a lower surface of the solar cell panel” in the present invention.

Furthermore, as shown in FIG. 4, in a portion of the gasket 3 along arrow X1 (X2), the grooves 31 formed in the upper inner surface 30a and the lower inner surface 30b are formed to extend in the direction X substantially orthogonal to the direction Y that is the extensional direction of the corresponding upper side surface 1b and lower side surface 1d of the solar cell panel 1. The grooves 31 formed in the side inner surface 30c are formed to extend in the direction Z substantially orthogonal to the direction Y.

As shown in FIG. 3, the flat portions 32 of the gasket 3 are configured to come into surface contact with the upper surface 1a in the vicinity of the end portions of the solar cell panel 1 and the upper side surfaces 1b and come into surface contact with the lower surface 1c in the vicinity of the second end portion 30e. Thus, the solar cell panel 1 is configured to be supported by the flat portions 32 of the gasket 3.

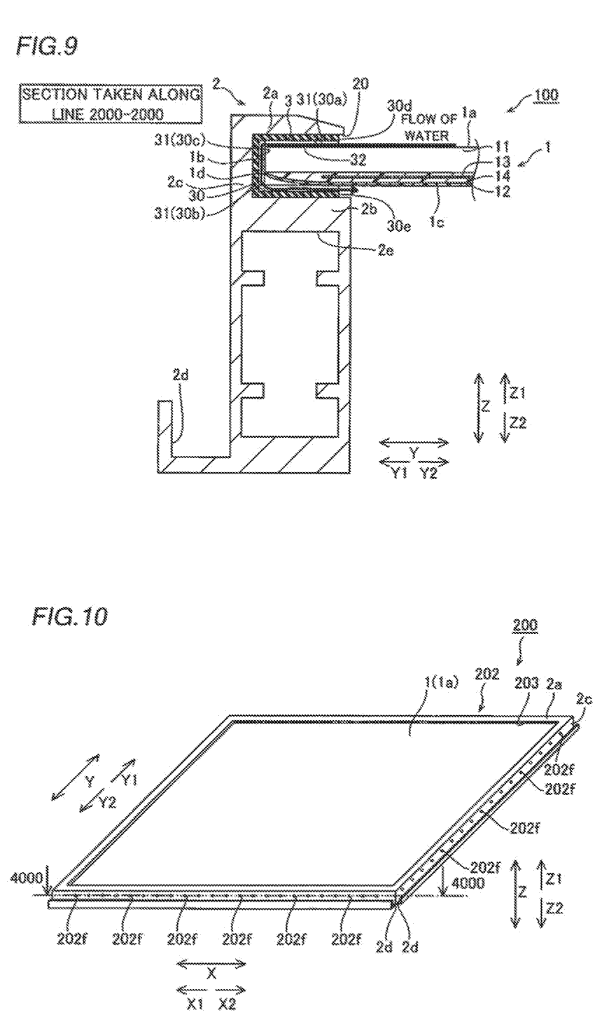

On the other hand, the grooves 31 of the gasket 3 are configured not to be in contact with any of the upper surface 1a, the upper side surfaces 1b, the lower surface 1c, and the lower side surfaces 1d of the solar cell panel 1, as shown in FIG. 9. Thus, water retained on the upper surface 1a of the solar cell panel 1 is discharged from the side of the lower surface 1c (along arrow Z2) of the solar cell panel 1 through flow channels formed by the grooves 31 of the gasket 3 and the upper surface 1a, the upper side surfaces 1b, the lower side surfaces 1d, and the lower surface 1c of the solar cell panel 1.

According to the first embodiment, as hereinabove described, the grooves 31 are formed in the inner surface 30 of the gasket 3, and formed to extend from the first end portion 30d to the second end portion 30e through the upper inner surface 30a, the side inner surface 30c, and the lower inner surface 30b, whereby the water retained on the upper surface 1a of the solar cell panel 1 can be discharged from the side of the lower surface 1c of the solar cell panel 1 through the grooves 31 of the gasket 3 extending from the first end portion 30d to the second end portion 30e. Furthermore, it is not necessary to form a flow channel by notching the upper portion 2a of the frame body 2 in order to discharge the water retained on the upper surface 1a of the solar cell panel 1, and hence the mechanical strength of the frame body 2 can be maintained. Therefore, the water retained on the upper surface 1a of the solar cell panel 1 can be discharged while the mechanical strength of the frame body 2 is maintained. In addition, the water retained on the upper surface 1a of the solar cell panel 1 can be reliably discharged as compared with a case where the grooves 31 are formed in the surface (outer surface of the gasket 3) opposite to the surface (inner surface 30) coming into contact with the solar cell panel 1.

According to the first embodiment, as hereinabove described, the grooves 31 are formed to extend in the directions substantially orthogonal to the extensional directions of the corresponding upper side surfaces 1b and lower side surfaces 1d of the solar cell panel 1 on the four sides of the gasket 3. Thus, the grooves 31 can extend from the end portion of the gasket 3 closer to the upper surface 1a of the solar cell panel 1 to the outside along a separating direction while the overall length of each of the grooves 31 in which water flows is reduced as compared with a case where the grooves 31 obliquely intersect with the extensional directions of the corresponding upper side surfaces 1b and lower side surfaces 1d of the solar cell panel 1, and hence the water retained on the upper surface 1a of the solar cell panel 1 can be more reliably discharged through the grooves 31.

According to the first embodiment, as hereinabove described, the grooves 31 are formed in the vicinity of the corners of the gasket 3 corresponding to the four corners of the solar cell panel 1, and the plurality of grooves 31 are formed in the substantially entire region of the four sides of the gasket 3 corresponding to the four sides of the solar cell panel 1, whereby the water retained on the upper surface 1a of the corner of the solar cell panel 1 arranged on the lower side can be discharged through the grooves 31 formed in the vicinity of the corner of the gasket 3 corresponding to the corner of the solar cell panel 1 when one of the four corners of the solar cell panel 1 is arranged below the other corners. Furthermore, when one of the four sides of the solar cell panel 1 is arranged below the other sides, the water retained on the upper surface 1a of the side of the solar cell panel 1 arranged on the lower side can be discharged through the plurality of grooves 31 formed in the substantially entire region of the side of the gasket 3 corresponding to the side of the solar cell panel 1 arranged on the lower side.

According to the first embodiment, as hereinabove described, the flat portions 32 formed between the respective adjacent grooves 31 are configured to come into surface contact with the upper surface 1a in the vicinity of the end portions of the solar cell panel 1 and the upper side surfaces 1b and come into surface contact with the lower surface 1c in the vicinity of the second end portion 30e, whereby the flow channels each having a closed periphery can be configured by the surface (the upper surface 1a, the upper side surfaces 1b, and the lower surface 1c) of the solar cell panel 1 and the grooves 31 of the gasket 3 supporting the solar cell panel 1 in a state where the flat portions 32 are in close contact with the solar cell panel 1. Thus, water can be inhibited from leaking from portions other than the grooves 31 during discharge.

### Second Embodiment

Next, a solar cell module 200 according to a second embodiment of the present invention is described with reference to FIGS. 3 and 10 to 16. In this second embodiment, a plurality of discharge holes 202f are formed in a frame body 202 while holes 233 are formed in a gasket 203, dissimilarly to the aforementioned first embodiment.

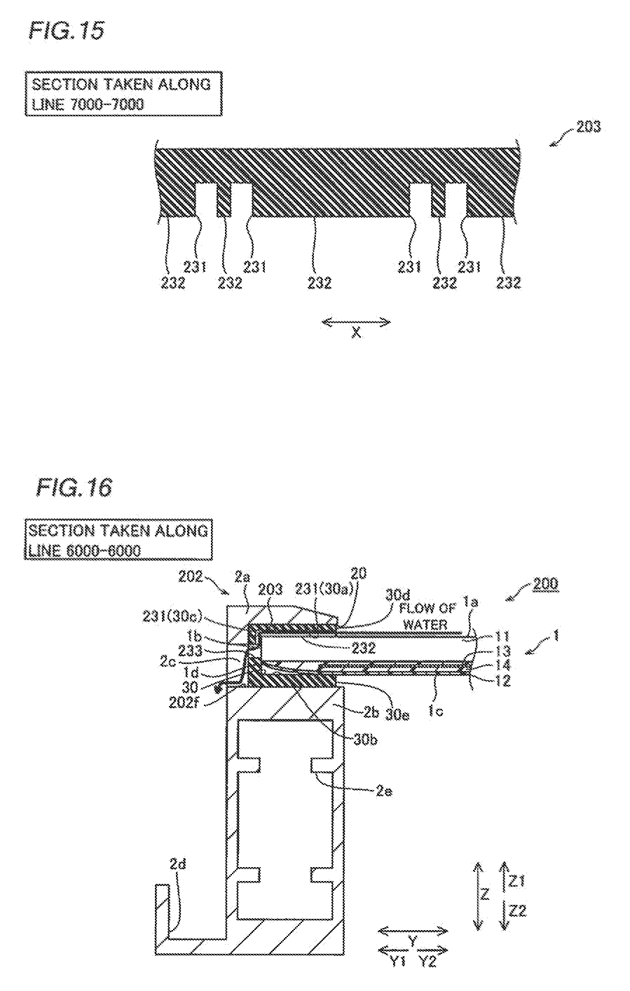

As shown in FIG. 10, the plurality of discharge holes 202f are formed at prescribed intervals on the four sides of the frame body 202 of the solar cell module 200 according to the second embodiment. As shown in FIG. 16, these discharge holes 202f are formed in side surface portions 2c of the frame body 202 opposed to upper side surfaces 1b of a solar cell panel 1, and formed to pass through the side surface portions 2c in a direction Y.

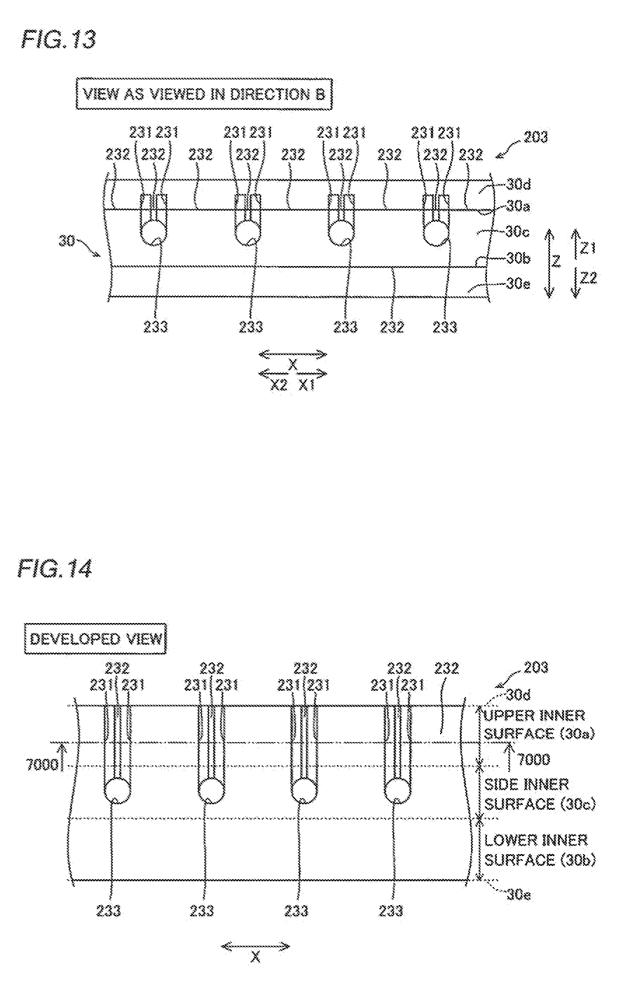

As shown in FIG. 12, pairs of grooves 231 are formed in an inner surface 30 of the gasket 203 on a side from which the solar cell panel 1 of the solar cell module 200 according to the second embodiment is inserted. These pairs of grooves 231 are formed at constant intervals as shown in FIGS. 13 and 14, and each have a substantially rectangular section as shown in FIG. 15. Regions of the inner surface 30 other than the grooves 231 are flat portions 232 each having a flat surface. As shown in FIG. 3, these flat portions 232 are configured to come into surface contact with an upper surface 1a in the vicinity of end portions of the solar cell panel 1 and the upper side surfaces 1b and come into surface contact with a lower surface is in the vicinity of a second end portion 30e.

According to the second embodiment, the holes 233 are formed in a side inner surface 30c of the inner surface 30 of the gasket 203, as shown in FIG. 12. These holes 233 are formed in regions of the side inner surface 30c corresponding to the upper side surfaces 1b of the solar cell panel 1, as shown in FIG. 16. The pairs of grooves 231 are formed to extend from a first end portion 30d to the common holes 233 formed in the side inner surface 30c through an upper inner surface 30a. In other words, the pairs of grooves 231 are connected to the common holes 233.

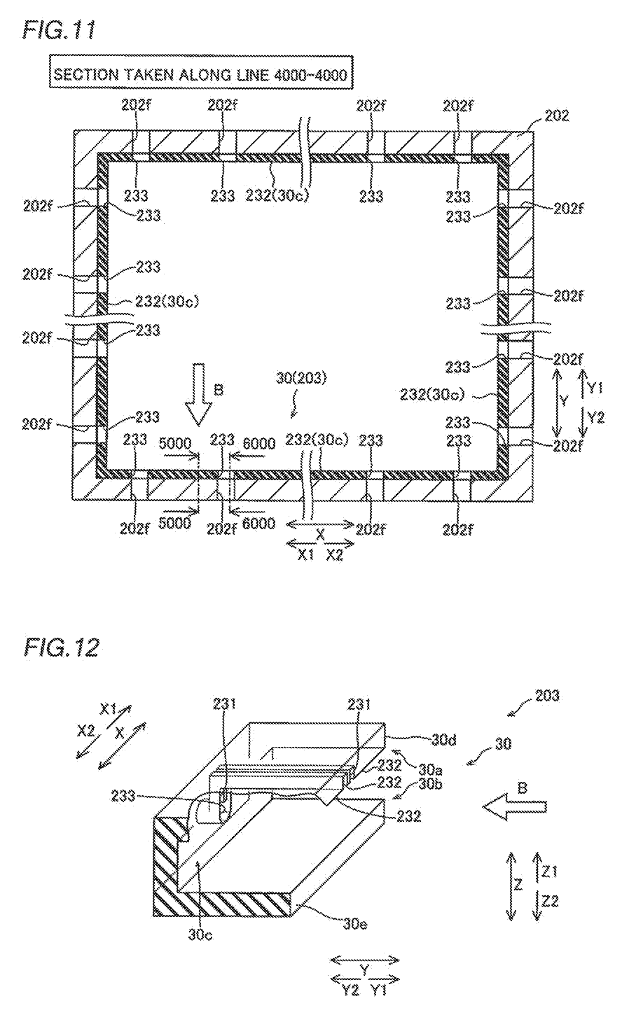

As shown in FIG. 11, the holes 233 of the gasket 203 are formed to be connected with the discharge holes 202f formed in the side surface portions 2c of the frame body 202. Thus, water flowing into the holes 233 of the gasket 203 can be discharged through the discharge holes 202f.

As shown in FIG. 16, the grooves 231 of the gasket 203 are configured not to be in contact with any of the upper surface 1a and the upper side surfaces 1b of the solar cell panel 1. Thus, water retained on the upper surface 1a of the solar cell panel 1 reaches the holes 233 of the gasket 203 through flow channels formed by the grooves 231 formed to extend from the first end portion 30d of the gasket 203 to an upper portion of the side inner surface 30c through the upper inner surface 30a and the upper surface 1a and parts of the upper side surfaces 1b of the solar cell panel 1. At this time, the water does not come into contact with the lower surface 1c and the lower side surfaces 1d of the solar cell panel 1.

The water reaching the holes 233 of the gasket 203 is discharged from the outer side (side opposite to a side on which the solar cell panel 1 is supported) of the solar cell panel 1 to external portions (outer peripheral grooves 2d) through the holes 233 of the gasket 203 and the discharge holes 202f of the frame body 202. The remaining structure of the second embodiment is similar to that of the aforementioned first embodiment.

According to the second embodiment, as hereinabove described, the grooves 231 are formed to extend from the first end portion 30d to the holes 233 formed in the side inner surface 30c through the upper inner surface 30a while the holes 233 are formed in the side inner surface 30c corresponding to the upper side surfaces 1b of the solar cell panel 1. Thus, the water retained on the upper surface 1a of the solar cell panel 1 is allowed to flow employing portions between a water-resistant upper surface-side cover 11 made of glass and the grooves 231 of the gasket 203 as flow channels, and the water can be easily discharged through the holes 233 formed in the regions of the side inner surface 30c corresponding to the upper side surfaces 1b of the solar cell panel 1. Thus, the water can be inhibited from flowing employing a portion between a lower surface-side cover 12 having relatively low water resistance as compared with the upper surface-side cover 11 and the gasket 203 as a flow channel. Consequently, the water can be inhibited from coming into contact with an interface between the upper surface-side cover 11 and the lower surface-side cover 12 and an interface between the upper surface-side cover 11 and a filler 14, and hence the water can be further inhibited from entering the inside of the solar cell panel 1. Furthermore, even if the filler 14 is exposed from the lower side surfaces 1d of the solar cell panel 1, the water does not come into contact with the lower side surfaces 1d so that the water can be further inhibited from entering the inside of the solar cell panel 1 through the filler 14.

According to the second embodiment, as hereinabove described, the pairs of grooves 231 are formed to extend to the common holes 233. Thus, even if a plurality of grooves 231 are close to each other and it is difficult to provide a hole 233 with respect to each of the plurality of grooves 231, a common hole 233 is formed with respect to each of the pairs of grooves 231 so that the holes 233 serving as discharge portions can be reliably formed in the gasket 203.

According to the second embodiment, as hereinabove described, the water retained on the upper surface 1a of the solar cell panel 1 is discharged through the grooves 231 and the holes 233 of the gasket 203 and the discharge holes 202f provided in the side surface portions 2c of the frame body 202, whereby the water discharged to the side of the gasket 202 closer to the frame body 202 through the grooves 231 and the holes 233 of the gasket 203 can be discharged to the external portions (outer peripheral grooves 2d) of the frame body 202 through the discharge holes 202f provided in the side surface portions 2c of the frame body 202. Furthermore, the discharge holes 202f to discharge the water to the external portions are provided in the side surface portions 2c of the frame body 202, whereby the mechanical strength of the frame body 202 can be further maintained as compared with a case where an upper portion 2a of the frame body 202 is notched.

According to the second embodiment, as hereinabove described, the holes 233 of the gasket 203 are formed to be connected with the discharge holes 202f formed in the side surface portions 2c of the frame body 202, whereby the water discharged to the holes 233 through the grooves 231 can be reliably discharged to the external portions through the holes 233 and the discharge holes 202f connected to the holes 233.

The remaining effects of the second embodiment are similar to those of the aforementioned first embodiment.

### Modification of Second Embodiment

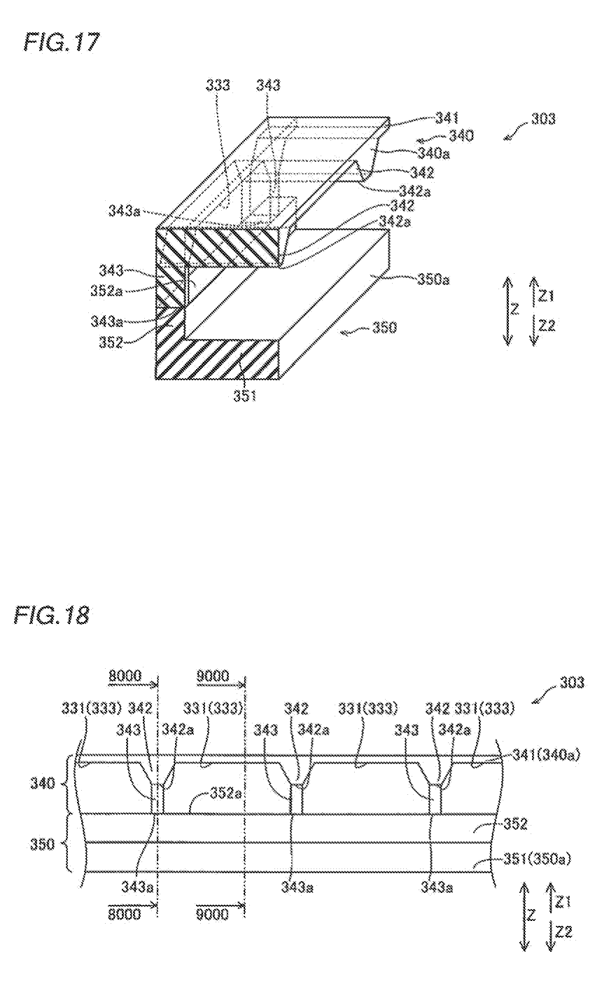

Next, a solar cell module 300 according to a modification of the second embodiment of the present invention is described with reference to FIGS. 17 to 20. In this modification of the second embodiment, a gasket 303 is constituted by an upper gasket 340 and a lower gasket 350, dissimilarly to the aforementioned second embodiment in which the gasket 203 is integrally formed.

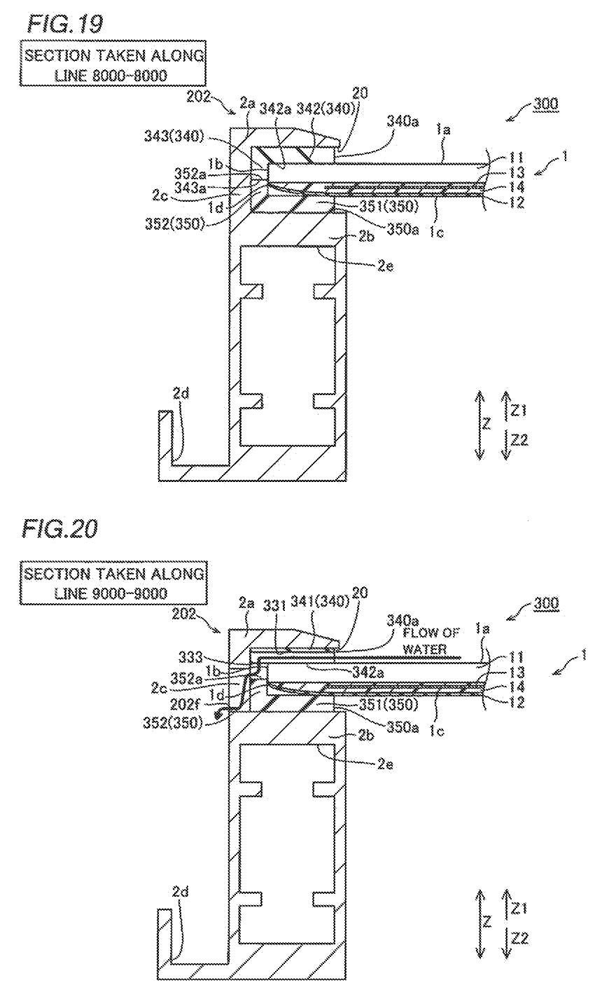

As shown in FIGS. 17 and 18, the gasket 303 of the solar cell module 300 according to the modification of the second embodiment is constituted by the upper gasket 340 and the lower gasket 350. This upper gasket 340 is formed with an upper surface portion 341, protrusion portions 342 formed at constant intervals to protrude downward (along arrow Z2) from the upper surface portion 341, and contact portions 343 formed on a side opposite to a side from which a solar cell panel 1 is inserted (see FIGS. 19 and 20), extending downward from the protrusion portions 342. These protrusion portions 342 have flat portions 342a coming into surface contact with an upper surface 1a in the vicinity of end portions of the solar cell panel 1. The contact portions 343 are configured to come into surface contact with the upper side surfaces 1b of the solar cell panel 1.

The lower gasket 350 is formed with a lower surface portion 351 and a contact portion 352 formed on the side opposite to the side from which the solar cell panel 1 is inserted, protruding upward (along arrow Z1) from the lower surface portion 351. This lower surface portion 351 is configured to come into surface contact with a lower surface 1c in the vicinity of an end portion 350a of the lower gasket 350 on the side from which the solar cell panel 1 is inserted, as shown in FIGS. 19 and 20. The contact portion 352 is configured to come into surface contact with parts of the upper side surfaces 1b of the solar cell panel 1. Furthermore, the upper surface 352a of the contact portion 352 comes into contact with the lower surfaces 343a of the contact portions 343 of the upper gasket 340 on the side opposite to the side from which the solar cell panel 1 is inserted.

Thus, in regions of the gasket 303 where no protrusion portion 342 of the upper gasket 340 is formed, grooves 331 extending from an end portion 340a on the side from which the solar cell panel 1 is inserted to the side opposite the side from which the solar cell panel 1 is inserted are formed by the upper surface portion 341 of the upper gasket 340 and the protrusion portions 342, as shown in FIG. 20. Furthermore, in regions of the gasket 303 other than the protrusion portions 342 of the upper gasket 340 and the contact portion 352, holes 333 are formed by the upper surface portion 341 of the upper gasket 340 and the contact portion 352 of the lower gasket 350, as shown in FIG. 18. The solar cell module 300 is so configured that water is discharged therefrom through these holes 333 and discharge holes 202f formed in side surface portions 2c of a frame body 202. At this time, the water does not come into contact with the lower surface 1c and the lower side surfaces 1d of the solar cell panel 1. Consequently, the water can be inhibited from coming into contact with an interface between an upper surface-side cover 11 and a lower surface-side cover 12 and an interface between the upper surface-side cover 11 and a filler 14, and hence the water can be further inhibited from entering the inside of the solar cell panel 1. Furthermore, even if the filler 14 is exposed from the lower side surfaces 1d of the solar cell panel 1, the water does not come into contact with the lower side surfaces 1d so that the water can be further inhibited from entering the inside of the solar cell panel 1 through the filler 14.

The remaining structure and the remaining effects of the modification of the second embodiment are similar to those of the aforementioned second embodiment.

### Third Embodiment

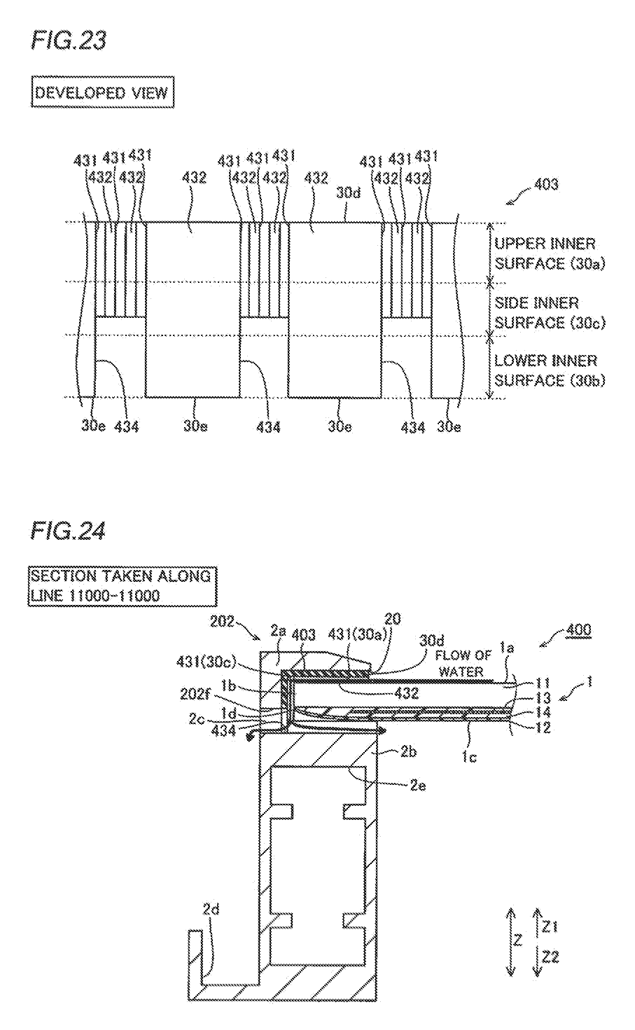

Next, a solar cell module 400 according to a third embodiment of the present invention is described with reference to FIGS. 3 and 21 to 24. In this third embodiment, notches 434 are formed in a gasket 403, dissimilarly to the aforementioned second embodiment in which the holes 233 are provided in the gasket 203.

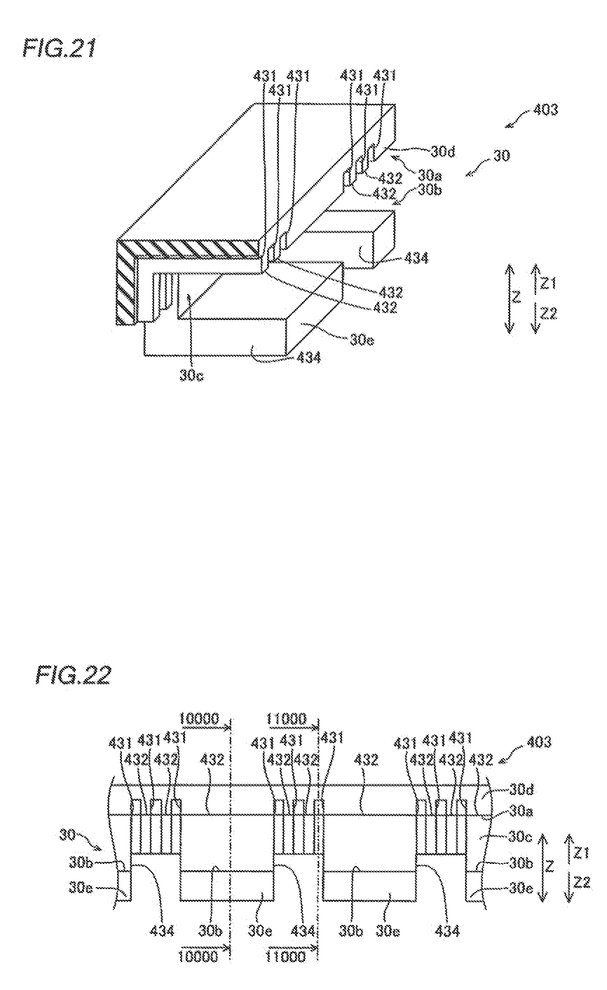

As shown in FIGS. 21 and 22, sets of three grooves 431 are formed at constant intervals in the inner surface 30 of the gasket 403 of the solar cell module 400 according to the third embodiment. Regions of the inner surface 30 other than the grooves 431 are flat portions 432 each having a substantially flat surface. As shown in FIG. 3, these flat portions 432 are configured to come into surface contact with an upper surface 1a in the vicinity of end portions of a solar cell panel 1 and upper side surfaces 1b and come into surface contact with a lower surface 1c in the vicinity of a second end portion 30e.

According to the third embodiment, the notches 434 are formed from the end portion 30e of the lower inner surface 30b of the inner surface 30 of the gasket 403 to parts of a side inner surface 30c on the side of the lower inner surface 30b, as shown in FIGS. 21 to 23. The sets of three grooves 431 are formed to extend from a first end portion 30d to the common notches 434 formed in the side inner surface 30c through an upper inner surface 30a. In other words, the sets of three grooves 431 are connected to the common notches 434.

As shown in FIG. 24, the notches 434 of the gasket 403 are formed to be connected with discharge holes 202f provided in side surface portions 2c of a frame body 202. Thus, water flowing into the notches 434 of the gasket 403 can be discharged to external portions (outer peripheral grooves 2d) through the discharge holes 202f. Furthermore, the notches 434 of the gasket 403 are formed also in the lower inner surface 30b of the inner surface 30, whereby the water flowing into the notches 434 of the gasket 403 can be discharged from the side of the lower surface 1c (along arrow Z2) of the solar cell panel 1 through a flow channel formed by the lower surface (surface along arrow Z2) of a recess portion 20 of the frame body 202 and the lower surface is of the solar cell panel 1. The remaining structure of the third embodiment is similar to that of the aforementioned second embodiment.

According to the third embodiment, as hereinabove described, the notches 434 are formed in the lower inner surface 30b and regions of the parts of the side inner surface 30c on the side of the lower inner surface 30b of the inner surface 30 of the gasket 403. Thus, water retained on the upper surface 1a of the solar cell panel 1 can be discharged through the grooves 431 and the notches 434 of the gasket 403 and the discharge holes 202f.

According to the third embodiment, as hereinabove described, the sets of three grooves 431 are formed to extend from the first end portion 30d to the common notches 434 formed in the side inner surface 30c through the upper inner surface 30a, whereby the water retained on the upper surface 1a of the solar cell panel 1 can be reliably discharged through the grooves 431 of the gasket 403 and the notches 434 connected to the grooves 431. Furthermore, even if a plurality of grooves 431 are close to each other and it is difficult to provide a notch 434 with respect to each of the plurality of grooves 431, a common notch 434 is formed with respect to each of the sets of three grooves 431 so that the notches 434 serving as discharge portions can be reliably formed in the gasket 403.

According to the third embodiment, as hereinabove described, the water retained on the upper surface 1a of the solar cell panel 1 is discharged through the grooves 431 and the notches 434 of the gasket 403 and the discharge holes 202f provided in the side surface portions 2c of the frame body 202, whereby water discharged to the side of the gasket 403 closer to the frame body 202 through the grooves 431 and the notches 434 of the gasket 403 can be discharged to the external portions (outer peripheral grooves 2d) of the frame body 202 through the discharge holes 202f provided in the side surface portions 2c of the frame body 202.

The remaining effects of the third embodiment are similar to those of the aforementioned first embodiment.

### Modification of Third Embodiment

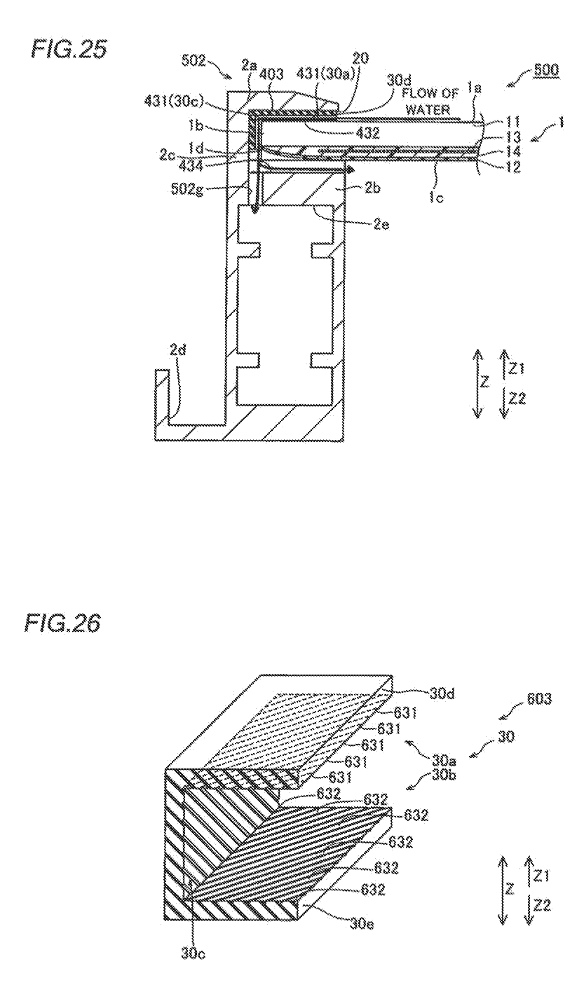

Next, a solar cell module 500 according to a modification of the third embodiment of the present invention is described with reference to FIG. 25. In this modification of the third embodiment, discharge holes 502g are provided in a lower portion 2b of a frame body 502, dissimilarly to the aforementioned third embodiment in which the discharge holes 202f are formed in the side surface portions 2c of the frame body 202.

As shown in FIG. 25, the discharge holes 502g are formed in the lower portion 2b of the frame body 502 of the solar cell module 500 according to the modification of the third embodiment. The discharge holes 502g are formed to pass through the lower portion 2b of the frame body 502 in a direction Z. Thus, water reaching the discharge holes 502g through grooves 431 and notches 434 of a gasket 403 passes through the discharge holes 502g and hollow portions 2e, and thereafter is discharged to external portions (outer peripheral grooves 2d) through unshown holes connected with the outer peripheral grooves 2d.

The remaining structure of the modification of the third embodiment is similar to that of the aforementioned third embodiment.

According to the modification of the third embodiment, as hereinabove described, water retained on the upper surface 1a of a solar cell panel 1 is discharged through the grooves 431 and the notches 434 of the gasket 403 and the discharge holes 502g provided in the lower portion 2b of the frame body 502, whereby water discharged to the side of the gasket 403 closer to the frame body 502 through the grooves 431 and the notches 434 of the gasket 403 can be discharged to the external portions (outer peripheral grooves 2d) of the frame body 502 through the discharge holes 502g provided in the lower portion 2b of the frame body 502. Furthermore, the discharge holes 502g are provided in the lower portion 2b of the frame body 502, whereby water discharged to the lower portion 2b of the frame body 502 can be reliably discharged.

The remaining effects of the modification of the third embodiment are similar to those of the aforementioned first embodiment.

The embodiments disclosed this time must be considered as illustrative in all points and not restrictive. The range of the present invention is shown not by the above description of the embodiments but by the scope of claims for patent, and all modifications within the meaning and range equivalent to the scope of claims for patent are included.

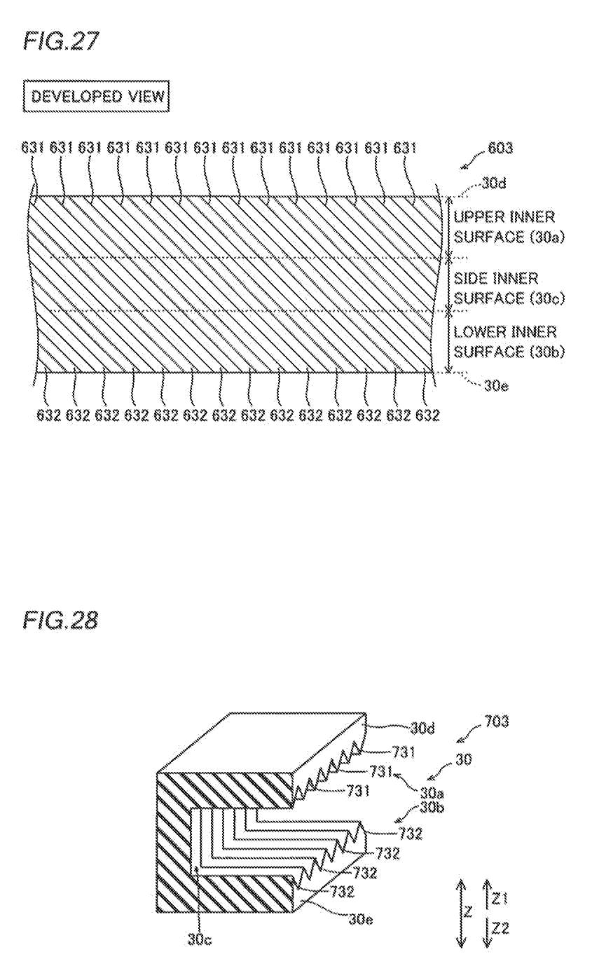

For example, while the grooves 31, 231, 331, or 431 of the gasket 3, 203, 303, or 403 are formed to extend in the directions substantially orthogonal to the extensional directions of the corresponding upper side surfaces 1b and lower side surfaces 1d of the solar cell panel 1 in each of the aforementioned first to third embodiments, the present invention is not restricted to this. For example, as in a first modification of each of the first to third embodiments shown in FIGS. 26 and 27, grooves 631 of a gasket 603 may be formed to obliquely extend in directions intersecting with extensional directions of the corresponding upper side surfaces and lower side surfaces of a solar cell panel. Furthermore, the grooves may be formed to extend to the holes according to the second embodiment or the notches according to the third embodiment formed in the gasket while being oblique in the directions intersecting with the extensional directions of the corresponding upper side surfaces and lower side surfaces of the solar cell panel.

While the grooves 31 extending from the first end portion 30d to the second end portion 30e are formed in the gasket 3 in the aforementioned first embodiment, the holes 233 and the grooves 231 extending to the holes 233 are formed in the gasket 203 in the aforementioned second embodiment, and the notches 434 and the grooves 431 extending to the notches 434 are formed in the gasket 403 in the aforementioned third embodiment, the present invention is not restricted to this. For example, a gasket having all of the structure of the first embodiment, the structure of the second embodiment, and the structure of the third embodiment may be prepared by separately providing regions where the grooves extending from the first end portion to the second end portion are formed, where the holes and the grooves extending to the holes are formed, and where the notches and the grooves extending to the notches in the gasket. Alternatively, a gasket having two of the structure of the first embodiment, the structure of the second embodiment, and the structure of the third embodiment may be prepared.

While the grooves 31, 231, 331, or 431 are formed in the substantially entire region of the four sides of the gasket 3, 203, 303, or 403 in each of the aforementioned first to third embodiments, the present invention is not restricted to this. According to the present invention, the grooves of the gasket may simply be formed at least in the vicinity of the corners of the gasket corresponding to the four corners of the solar cell panel.

While the grooves 31, 231, 331, or 431 are formed in the substantially entire region of the four sides of the gasket 3, 203, 303, or 403 in each of the aforementioned first to third embodiments, the present invention is not restricted to this. According to the present invention, the grooves of the gasket may be formed in a region corresponding to a partial region of the four sides of the solar cell panel.

While the holes 233 are formed in the regions of the side inner surface 30c corresponding to the upper side surfaces 1b of the solar cell panel 1 in the aforementioned second embodiment, the present invention is not restricted to this. According to the present invention, the holes may be formed in regions of the side inner surface corresponding to vicinities of boundaries between the upper side surfaces and the lower side surfaces. Alternatively, the holes may be formed in regions of the side inner surface corresponding to the lower side surfaces of the solar cell panel.

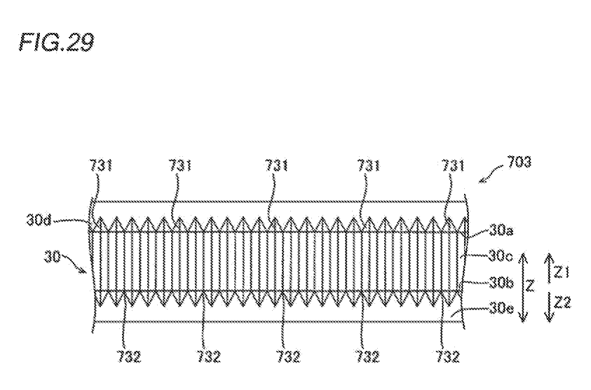

While the flat portions 32, 232, 342a, or 432 come into surface contact with the solar cell panel 1 in each of the aforementioned first to third embodiments, the present invention is not restricted to this. For example, as in a second modification of each of the first to third embodiments shown in FIGS. 28 and 29, apexes 732 of substantially triangular portions formed between a plurality of grooves 731 of a gasket 703 may come into contact with a solar cell panel.

While the grooves 31, 231, 331, or 431 are formed in the surface (inner surface 30) coming into contact with the solar cell panel 1 in each of the aforementioned first to third embodiments, the present invention is not restricted to this. According to the present invention, the grooves of the gasket may not be formed in the surface coming into contact with the solar cell panel but may be formed in a surface coming into contact with the frame body.

The present invention is also applicable to a solar cell module employing thin-film solar cells.

What is claimed is:

1. A solar cell module comprising:
a solar cell panel including a solar cell;
a frame body to support an end portion of said solar cell panel; and
a gasket including a groove to discharge water retained on an upper surface of said solar cell panel, arranged between said solar cell panel and said frame body.

2. The solar cell module according to claim 1, wherein
said solar cell panel has a substantially rectangular shape in plan view, and
said groove of said gasket extends from an end portion of said gasket closer to said upper surface of said solar cell panel to intersect with an extensional direction of a side surface of said solar cell panel on which said gasket is arranged.

3. The solar cell module according to claim 2, wherein
said groove of said gasket extends from said end portion of said gasket closer to said upper surface of said solar cell panel to be substantially orthogonal to said extensional direction of said side surface of said solar cell panel on which said gasket is arranged.

4. The solar cell module according to claim 1, wherein
said groove of said gasket is formed in a surface coming into contact with said solar cell panel.

5. The solar cell module according to claim 1, wherein
said groove of said gasket is formed in an end portion of said gasket closer to said upper surface of said solar cell panel and at least a region of said gasket corresponding to said upper surface of said solar cell panel.

6. The solar cell module according to claim 1, wherein
said solar cell panel has a substantially rectangular shape in plan view, and
said groove of said gasket is formed at least in the vicinity of four corners of said solar cell panel.

7. The solar cell module according to claim 1, wherein
said solar cell panel has a substantially rectangular shape in plan view, and
said groove of said gasket is formed in a region corresponding to at least a partial region of each of four sides of said solar cell panel.

8. The solar cell module according to claim 7, wherein
a plurality of said grooves of said gasket are formed in a region corresponding to a substantially entire region of said four sides of said solar cell panel.

9. The solar cell module according to claim 1, wherein
said gasket further includes a flat portion formed between a plurality of said grooves, coming into surface contact with said solar cell panel.

10. The solar cell module according to claim 1, wherein
said groove of said gasket extends from an end portion of said gasket closer to said upper surface of said solar cell panel to an end portion of said gasket closer to a lower surface of said solar cell panel.

11. The solar cell module according to claim 1, wherein
a hole is formed as a discharge portion in a region of said gasket corresponding to a side surface of said solar cell panel.

12. The solar cell module according to claim 11, wherein
said groove of said gasket is formed to be connected to said hole.

13. The solar cell module according to claim 12, wherein
said solar cell panel further includes an upper surface cover portion made of a water-resistant material, arranged on said upper surface of said solar cell panel and a lower surface cover portion arranged on a lower surface of said solar cell panel,
said groove of said gasket is formed in a surface coming into contact with said solar cell panel, and extends from an end portion of said gasket closer to said upper surface of said solar cell panel to said hole, and
said hole of said gasket is formed in a region corresponding to a vicinity of a boundary between said upper surface cover portion and said lower surface cover portion of said side surface of said solar cell panel or a region corresponding to a position closer to said upper surface of said solar cell panel beyond said vicinity of said boundary.

14. The solar cell module according to claim 12, wherein
a plurality of adjacent said grooves of said gasket are formed to be connected to common said hole.

15. The solar cell module according to claim 11, wherein
said frame body includes an upper portion located in a region corresponding to said upper surface of said solar cell panel, a lower portion located in a region corresponding to a lower surface of said solar cell panel, and a side surface portion located in a region corresponding to said side surface of said solar cell panel,
a discharge hole to discharge water is provided in said side surface portion of said frame body, and
said water retained on said upper surface of said solar cell panel is discharged through said groove and said hole of said gasket and said discharge hole of said side surface portion of said frame body.

16. The solar cell module according to claim 15, wherein
said hole of said gasket is formed to be connected to said discharge hole of said frame body.

17. The solar cell module according to claim 1, wherein
a notch is provided as a discharge portion in a region of said gasket corresponding to a lower surface of said solar cell panel.

18. The solar cell module according to claim 17, wherein
said groove of said gasket is formed to be connected to said notch.

19. The solar cell module according to claim 18, wherein
a plurality of adjacent said grooves of said gasket are formed to be connected to common said notch.

20. The solar cell module according to claim 17, wherein
said frame body includes an upper portion located in a region corresponding to said upper surface of said solar cell panel, a lower portion located in a region corresponding to said lower surface of said solar cell panel, and a side surface portion located in a region corresponding to a side surface of said solar cell panel,
a discharge hole to discharge water is provided in said side surface portion or said lower portion of said frame body, and
said water retained on said upper surface of said solar cell panel is discharged through said groove and said notch of said gasket and said discharge hole of said frame body.
